(19) United States
(12) Patent Application Publication
(10) Pub. No.: US 2005/0158947 A1
(43) Pub. Date: Jul. 21, 2005

(54) Method for Forming Self-Aligned Trench

(75) Inventors: Yi-Nan Su, Taipei (TW); Wen-Zheng Jian, Hua-Lien (TW)

Correspondence Address: SQUIRE, SANDERS & DEMPSEY L.L.P, 600 HANSEN WAY, PALO ALTO, CA, 94304-1043, US

(73) Assignee: United Microelectronics Corp., Hsin-Chu City (TW)

(21) Appl. No.: 10/759,594

(22) Filed: Jan. 16, 2004

(51) Int. Cl. H01L 21/8242

(52) U.S. Cl. 438/248

(57) ABSTRACT

A method for forming a self-aligned trench is disclosed. The steps of the method include providing a semiconductor substrate with a buried layer. A buffer layer and a first hard mask layer are formed sequentially on a surface of the semiconductor substrate. Parts of the first hard mask layer, the buffer layer and the semiconductor substrate are removed to form openings. A capacitor is formed in the interior of the opening of the semiconductor substrate. A second hard mask layer is formed conformally on the first hard mask layer and the capacitor. An insulator layer and a pattern photoresist layer are formed sequentially on the second hard mask layer. Parts of the insulator layer, the second hard mask layer, the first hard mask layer, the buffer layer, and the semiconductor substrate are removed, with a part of said insulator layer as a mask, to form a self-aligned trench in the middle between partial said two capacitors, wherein a different removing rate exists between the insulator layer and the second hard mask layer.

### BACKGROUND OF THE INVENTION

1. Field of the Invention

The present invention relates to the formation of shallow trench isolation. More particularly, the present invention relates to a method for fabricating a self-aligned shallow trench isolation (SASTI) above a deep trench structure.

2. Description of the Prior Art

The deep trench structure is widely used in the advanced process of the integrated circuit (IC) fabrication. For example, the deep trench (DT) capacitors are formed for electric charge storage in the dynamic random access memory (DRAM). According to the increasing of the surface area of the capacitors, it also enhances the performance of the DRAM. Generally, a DRAM cell is composed of an aforementioned DT capacitor and a complementary metal oxide semiconductor (CMOS) transistor. The CMOS transistor plays a role of ON/OFF switch in the DRAM cell. The conduction between the DT capacitor and the CMOS transistor is accomplished by an internal electrode, which is formed in the DT structure above the DT capacitor. The sheet resistance of the internal electrode is inverse related with its width. That means the narrower the width, the higher the sheet resistance. If the sheet resistance is too high to insulate the DT capacitor and CMOS transistor, then the DRAM cell will fail in data writing and reading.

The shallow trench isolation (STI) formation primarily effects the width of the internal electrode. Before the STI formation, the active area (AA) must be defined via mask alignment process. The displacement of AA is generated when there is a misalignment in mask alignment process. Then the over etching of the internal electrode is caused in the further STI etching process; even the whole internal electrode is possibly etched. Then a poor conduction between the DT capacitor and the CMOS transistor will have occurred.

Considering a DRAM cell illustrated in FIG. 1A, the CMOS transistor and irrelevant details are not drawn in order to make the illustrations concise and to provide a clear description for easy understanding of the problem within the prior art. A semiconductor substrate 101 with a buried layer 102 exists the formation of a pad oxide layer 103 and a pad nitride layer 104 on its surface. Two deep trenches 111 are generated in the semiconductor substrate 101 by an etching process. A deep trench (DT) capacitor 121 is formed in the interior of the deep trench 111 of the semiconductor substrate 101. Wherein the DT capacitor is composed of a lower electrode 122, a dielectric layer 123, an upper electrode 124, an oxide collar layer 125 and an internal electrode 126. There exist buried straps 105 in the joins of the vertical side-wall of the trench 111 and the surface of the semiconductor substrate 101. The DT capacitor 121 is conducted with the CMOS transistor (not shown) via the buried strap 105 and the internal electrode 126.

In the FIG. 1B, a thick hard mask layer 131 and a photoresist layer 132 are formed sequentially on the pad nitride layer 104. Then an active area (AA) 112 and a device area 113 are defined via mask alignment process. The CMOS transistor is further fabricated in the device area 113. The schematic diagram of the vertical view of the FIG. 1B is shown in FIG. 1C. If the active area (AA) border 142 cannot be matched with the central line 141 of the deep trench 111, then a misalignment 143 is generated.

In FIG. 1D, parts of the thick hard mask layer 131, the pad nitride layer 104, the pad oxide layer 103 and the semiconductor substrate 101 are etched to form a shallow trench isolation (STI) area 114. Due to the misalignment 143 generated in the previous process, the internal electrode 126 of the left DT capacitor 121 is over etched, possibly completely etched. As a result poor conduction may occur or the insulation between the DT capacitor 121 and the CMOS transistor will cause the DRAM cell to fail. How to provide an efficient method to form a STI area with no over etching of the internal electrode is the primary purpose of the present invention.

### SUMMARY OF THE INVENTION

In accordance with the background of the above-mentioned invention, the conventional method can not form the needed shallow trench isolation (STI) above a deep trench structure in an efficient method. One objective of the present invention is to provide a method for fabricating a self-aligned shallow trench isolation above a deep trench structure. Therefore the misalignment problem between the internal electrode of the capacitor and the shallow trench isolation in the conventional method can be avoided.

The other objective of the present invention is to provide a structure of a self-aligned shallow trench isolation above a deep trench structure. The high resistance problem between a source/drain region and the internal electrode of the capacitor can be solved.

In accordance with the present invention, a method for forming a self-aligned trench is disclosed. The steps of the method include providing a semiconductor substrate with a buried layer. A buffer layer and a first hard mask layer are formed sequentially on a surface of the semiconductor substrate. Parts of the first hard mask layer, the buffer layer and the semiconductor substrate are removed to form openings. A capacitor is formed in the interior of the opening of the semiconductor substrate. A second hard mask layer is formed conformally on the first hard mask layer and the capacitor. An insulator layer and a pattern photoresist layer are formed sequentially on the second hard mask layer. Parts of the insulator layer, the second hard mask layer, the first hard mask layer, the buffer layer, and the semiconductor substrate are removed, with a part of said insulator layer as a mask, to form a self-aligned trench in the middle between partial said two capacitors, wherein a different removing rate exists between the insulator layer and the second hard mask layer.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:.

FIG. 1A is a semiconductor substrate with a deep trench (DT) capacitor in the prior art;

FIG. 1B is a semiconductor substrate with an active area (AA) formed in the prior art;

FIG. 1C is a schematic diagram of the vertical view of the FIG. 1B;

FIG. 1D is an over etching of the internal electrode in the prior art;

FIG. 2A-2D are a series of cross-sectional schematic diagrams of the embodiment of the present invention.

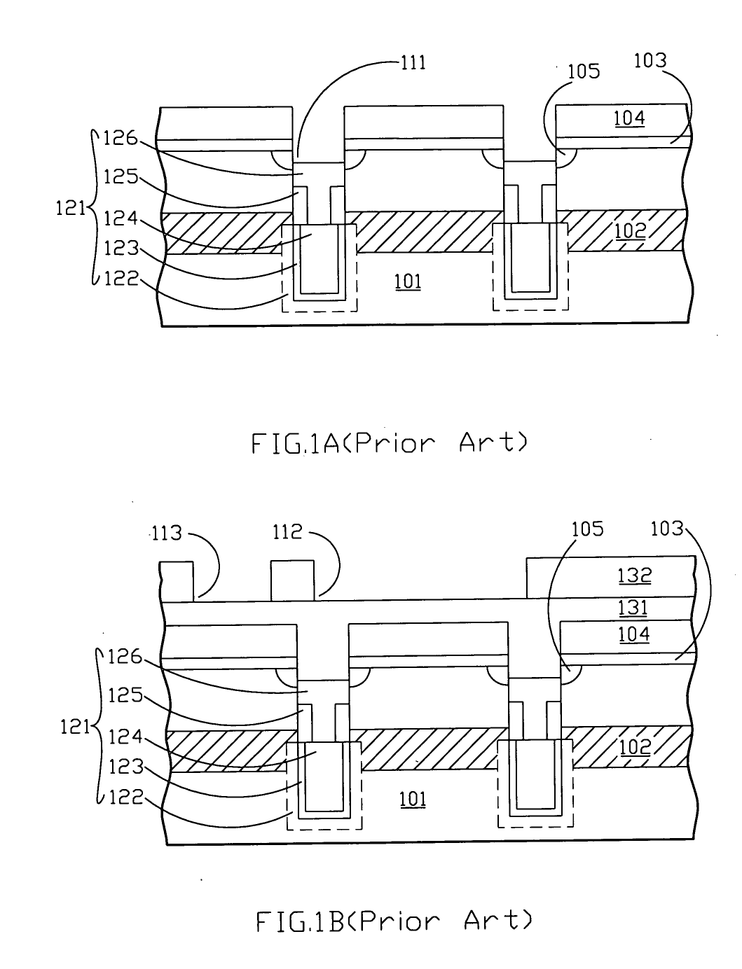

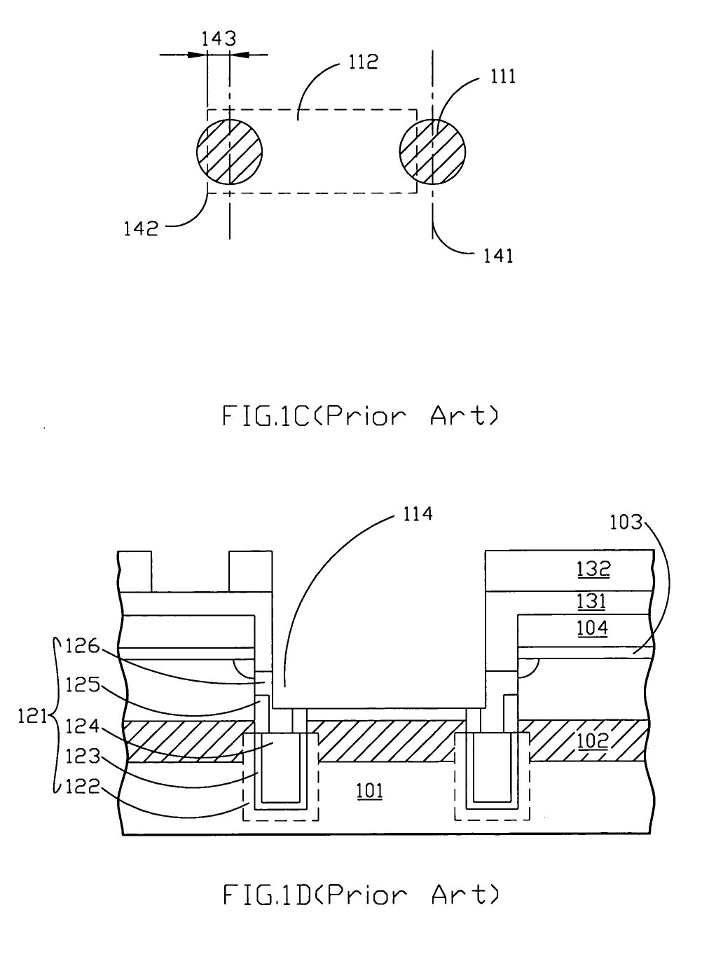

### DESCRIPTION OF THE PREFERRED EMBODIMENTS

There is shown a representative portion of a semiconductor structure of the present invention which is enlarged, cross-sections of the two dimensional views at several stages of fabrication. The drawings are not necessarily to scale, as the thickness of the various layers are shown for clarify the illustration and should not be interpreted in a limiting sense. Accordingly, these regions will have dimensions, including length, width and depth, when fabricated in an actual device.

A method for forming a self-aligned trench is disclosed. The steps of the method include providing a semiconductor substrate with a buried layer. A buffer layer and a first hard mask layer are formed sequentially on a surface of the semiconductor substrate. Parts of the first hard mask layer, the buffer layer and the semiconductor substrate are removed to form openings. A capacitor is formed in the interior of the opening of the semiconductor substrate. A second hard mask layer is formed conformally on the first hard mask layer and the capacitor. An insulator layer and a pattern photoresist layer are formed sequentially on the second hard mask layer. Parts of the insulator layer, the second hard mask layer, the first hard mask layer, the buffer layer, and the semiconductor substrate are removed, with a part of said insulator layer as a mask, to form a self-aligned trench in the middle between partial said two capacitors, wherein a different removing rate exists between the insulator layer and the second hard mask layer.

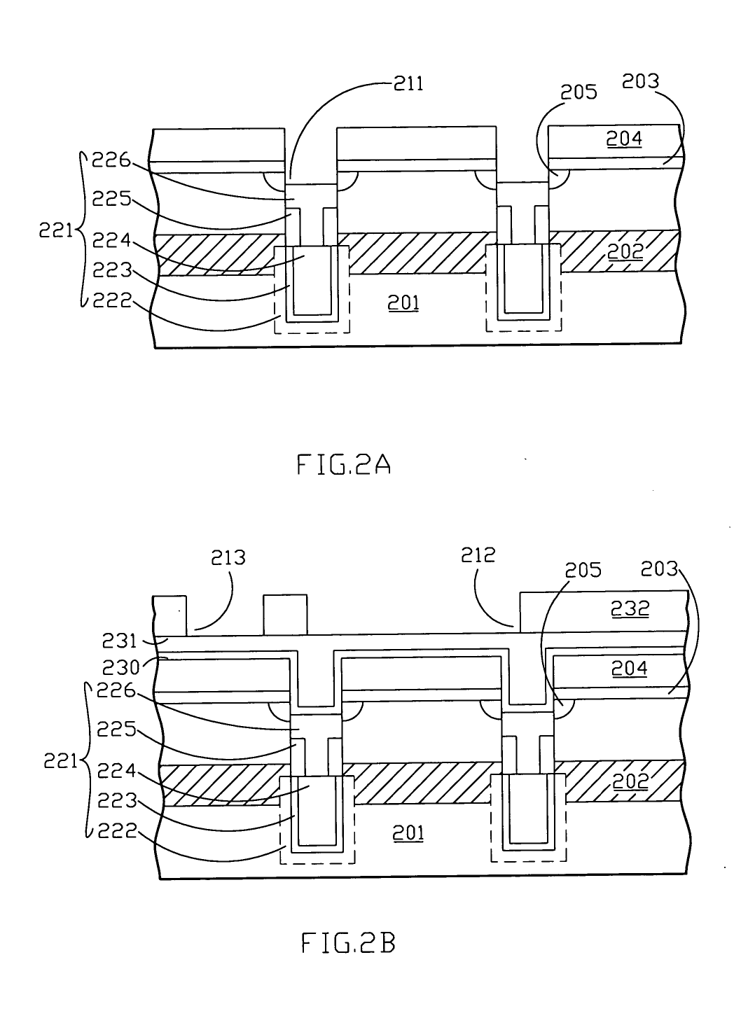

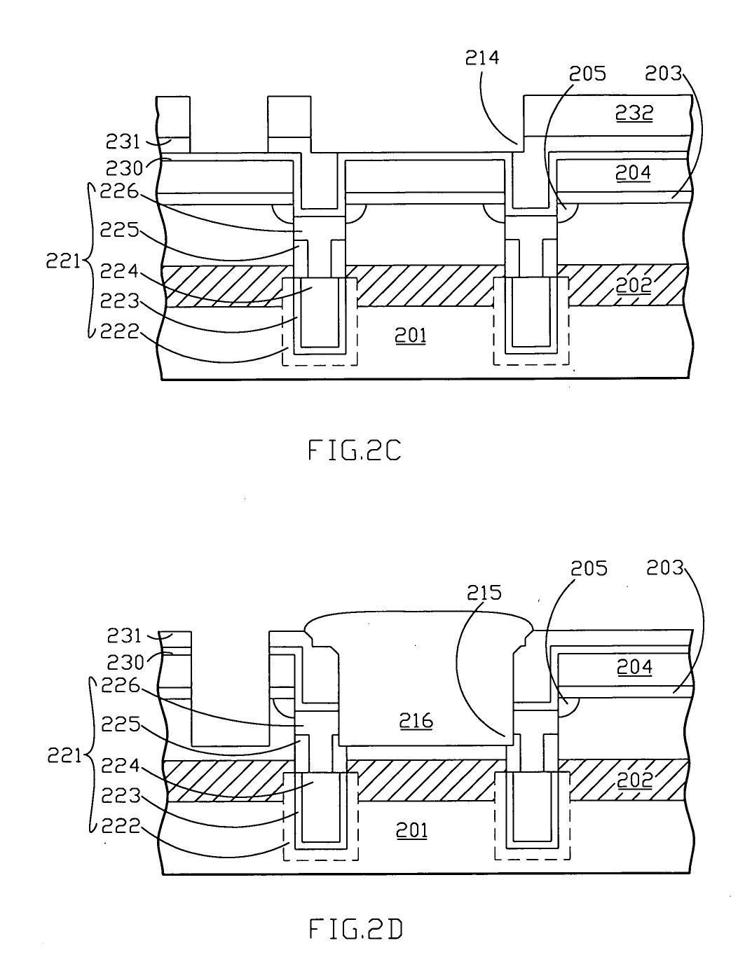

One embodiment of the present invention is depicted in FIGS. 2A-2D. First referring to FIG. 2A, a semiconductor substrate 201 with a buried layer 202 is first provided, wherein a doping type of the buried layer 202 is different from the doping type of the semiconductor substrate 201. Next, a buffer layer and a first hard mask layer, such as a pad oxide layer 203 and a pad nitride layer 204, are sequentially formed on a surface of the semiconductor substrate 201. Then, a photoresist layer (not shown) which has holes is formed on the surface of the pad nitride layer 204 to expose the pad nitride layer 204. Etching parts of the pad nitride layer 204, the pad oxide layer 203 and the semiconductor substrate 201 to form two first openings, such as deep trenches (DT) 211, through the pad nitride layer 204, the pad oxide layer 203, and into the semiconductor substrate 201. The depth of the deep trench (DT) 211 is usually about 7-8 μm.

Referring to FIG. 2A, two DT capacitors 221 are formed in the interior of the two deep trenches (DT) 211 of the semiconductor substrate 201. The DT capacitor 221 is composed of a lower electrode 222, a first dielectric layer 223, an upper electrode 224, a dielectric collar layer 225 and an internal electrode 226. Steps of fabricating the DT capacitor 221 include forming a lower electrode 222 diffused into a lower portion of the deep trench (DT) 211 of the semiconductor substrate 201, forming a first dielectric layer 223 and an upper electrode 224 filled into the lower portion of the deep trench (DT) 211 of the semiconductor substrate 201, forming a dielectric collar layer 225 on a side-wall of the deep trench (DT) 211 above the upper electrode 224, wherein the dielectric collar layer 225 covers an exposed surface of the first dielectric layer 223 within the deep trench (DT) 211 but not fully covers the exposed surface of the upper electrode 224, and forming an internal electrode 226 on both the dielectric collar layer 225 and the upper electrode 224. Buried straps 205 are formed in the joins of a side-wall of the two deep trenches 211 and the surface of the semiconductor substrate 201. The DT capacitor is conducted with CMOS transistors (not shown) via the buried strap 205 and the internal electrode 226.

Referring to FIG.2B, one of the features of the present invention, a thin hard mask layer, such as bottom anti-reflective coating (BARC) 230, is conformally formed on the pad nitride layer 204. The thickness of the BARC 230 is about one third to one sixth width of the deep trench 211 so that the BARC 230 is incompletely filled into the deep trench 211. Next, an insulator layer, such as a second dielectric layer 231 or a nitride layer or an oxide layer, is formed on the BARC 230 and filled into the deep trench 211 completely. A pattern photoresist layer 232 which defines an active area (AA) 212 and a device area 213 is coated on the second dielectric layer 231. The CMOS transistor is further fabricated in the device area 213.

An effect of etching selectivity is generated according to different materials with different removing rates. Referring to FIG. 2C, the other of the features of the present invention, according to a high etching selectivity of the second dielectric layer 231 comparing with the BARC 230, a part of the second dielectric layer 231 is etched to form a second opening 214 which stops etching on the top of the BARC 230. In the embodiment, the high etching selectivity of etching away the second dielectric layer 231 with respect to the BARC 230 of more than 8 to 1. Next, the pattern photoresist layer 232 is striped. Referring to FIG. 2D, according to the high etching selectivity between the second dielectric layer 231, the BARC 230, the pad nitride layer 204, the pad oxide layer 203 and the semiconductor substrate 201, parts of the BARC 230, the pad nitride layer 204, the pad oxide layer 203 and the semiconductor substrate 201 are etched, with a part of said second dielectric layer 231 as a mask, to form a self-aligned trench 215 in the middle between partial said two DT capacitors 221. Finally, an insulator 216, such as an oxide, is filled into the self-aligned trench 215 completely to form a shallow trench isolation (STI). The depth of the shallow trench isolation (STI) is usually about 3000-4000 angstroms.

The fabrication method of the present invention is a self-aligned process for forming a trench isolation in the middle between partial two DT capacitors, and the misalignment problem between the internal electrodes of the DT capacitors and the trench isolation in the conventional method can be avoided.

Above said preferred embodiment is only used to illustrate the present invention, not intended to limit the scope thereof. Many modifications of the preferred embodiment can be made without departing from the spirit of the present invention.

1. A method for forming a self-aligned trench, said method comprising:
providing a semiconductor substrate having a first hard mask layer thereon and openings therein, wherein a capacitor is formed in the interior of said opening of said semiconductor substrate;
conformally forming a second hard mask layer on said first hard mask layer and said capacitor;
forming an insulator layer on said second hard mask layer;
forming a pattern photoresist layer on said insulator layer; and
removing parts of said insulator layer, said second hard mask layer, said first hard mask layer and said semiconductor substrate, with a part of said insulator layer as a mask, to form a trench in the middle between partial said two capacitors, wherein a different removing rate exists between said insulator layer and said second hard mask layer.

2. The method of claim 1; further comprising:
forming an isolation into said trench.

3. The method of claim 2, wherein said isolation comprises an oxide.

4. The method of claim 2, wherein the depth of said trench is about 3000-4000 angstroms.

5. The method of claim 1, wherein steps of providing said semiconductor substrate comprise:
doping a buried layer into said semiconductor substrate, wherein a doping type of said buried layer is different from the doping type of said semiconductor substrate;
forming a buffer layer and said first hard mask layer sequentially on a surface of said semiconductor substrate;
forming a photoresist which has holes on a surface of said first hard mask layer to expose said first hard mask layer; and
removing parts of said first hard mask layer, said buffer layer and said semiconductor substrate to form said openings.

6. The method of claim 5, wherein said buffer layer comprises an oxide layer.

7. The method of claim 1, wherein steps of forming said capacitor comprise:
forming a lower electrode diffused into a lower portion of said opening of said semiconductor substrate;
forming a first dielectric layer and an upper electrode filled into said lower portion of said opening of said semiconductor substrate;
forming a dielectric collar layer on a side-wall of said opening above said upper electrode, wherein said dielectric collar layer covers an exposed surface of said first dielectric layer within said opening but not fully covers said exposed surface of said upper electrode; and
forming an internal electrode on both said dielectric collar layer and said upper electrode.

8. The method of claim l,wherein the depth of said opening is about 7-8 μm.

9. The method of claim 1, wherein buried straps exist in the joins of a side-wall of said opening and a surface of said semiconductor substrate.

10. The method of claim 9, wherein said capacitor is conducted with a CMOS transistor via said buried straps and said internal electrode.

11. The method of claim 1, wherein the thickness of said second hard mask layer is about one third to one sixth width of said opening.

12. The method of claim 1, wherein said pattern photoresist layer defines an active area (AA) and a device area via mask alignment process.

13. The method of claim 12, wherein a CMOS transistor is further fabricated in said device area.

14. The method of claim 1, wherein said first hard mask layer comprises a nitride layer.

15. The method of claim 1, wherein said second hard mask layer comprises a bottom anti-reflective coating (BARC).

16. The method of claim 1, wherein said insulator layer comprises a dielectric layer.

17. The method of claim 1, wherein said different removing rate is a selectivity of etching away said insulator layer with respect to said second hard mask layer of more than 8 to 1.

18. A method for forming a self-aligned trench isolation, said method comprising:
providing a semiconductor substrate having a pad nitride layer thereon and openings therein, wherein a capacitor is formed in the interior of said opening of said semiconductor substrate;
conformally forming a hard mask layer on said pad nitride layer and said capacitor;
forming a dielectric layer on said hard mask layer;
forming a pattern photoresist layer on said dielectric layer;
removing parts of said dielectric layer, said hard mask layer, said pad nitride layer and said semiconductor substrate, with a part of said dielectric layer as a mask, to form a trench in the middle between partial said two capacitors, wherein a removing rate between said dielectric layer and said hard mask layer is different; and
filling an insulator into said trench to form a trench isolation.

19. The method of claim 18, wherein steps of providing said semiconductor substrate comprise:
doping a buried layer into said semiconductor substrate, wherein a doping type of said buried layer is different from the doping type of said semiconductor substrate;
forming a pad oxide layer and said pad nitride layer sequentially on a surface of said semiconductor substrate;
forming a photoresist which has holes on a surface of said pad nitride layer to expose said pad nitride layer; and
removing parts of said pad nitride layer, said pad oxide layer and said semiconductor substrate to form said openings.

20. The method of claim 18, wherein steps of forming said capacitor comprise:
forming a lower electrode diffused into a lower portion of said opening of said semiconductor substrate;
forming a first dielectric layer and an upper electrode filled into said lower portion of said opening of said semiconductor substrate;
forming a dielectric collar layer on a side-wall of said opening above said upper electrode, wherein said dielectric collar layer covers an exposed surface of said first dielectric layer within said opening but not fully covers said exposed surface of said upper electrode; and
forming an internal electrode on both said dielectric collar layer and said upper electrode.

21. The method of claim 18, wherein the depth of said opening is about 7-8 μm.

22. The method of claim 18, wherein buried straps exist in the joins of a side-wall of said opening and a surface of said semiconductor substrate.

23. The method of claim 22, wherein said capacitor is conducted with a CMOS transistor via said buried strap and said internal electrode.

24. The method of claim 18, wherein the thickness of said hard mask layer is about one third to one sixth width of said opening.

25. The method of claim 18, wherein said pattern photoresist layer defines an active area (AA) and a device area via mask alignment process.

26. The method of claim 25, wherein a CMOS transistor is further fabricated in said device area.

27. The method of claim 18, wherein said hard mask layer comprises a bottom anti-reflective coating (BARC).

28. The method of claim 18, wherein said removing rate between said dielectric layer and said hard mask layer is a selectivity of etching away said dielectric layer with respect to said hard mask layer of more than 8 to 1.

29. The method of claim 18, wherein said insulator comprises an oxide.

30. The method of claim 18, wherein the depth of said trench is about 3000-4000 angstroms.
